(19) United States
(12) Patent Application Publication
(10) Pub. No.: US 2006/0022317 A1
(43) Pub. Date: Feb. 2, 2006

(54) Chip-under-tape package structure and manufacture thereof

(76) Inventors: An-Hong Liu, Tainan City (TW); Chao Yung Ching, Taichung City (TW); Yao Jung Lee, Rende Township (TW); Yi-Chang Lee, Tainan City (TW); Hsiang-Ming Huang, Tainan City (TW)

Correspondence Address: Hoffman, Warnick & D'Alessandro LLC, 14th Floor, 75 State Street, Albany, NY, 12207, US

(21) Appl. No.: 11/180,494

(22) Filed: Jul. 13, 2005

(30) Foreign Application Priority Data
Jul. 14, 2004 (TW) 093121053

(51) Int. Cl. H01L 21/50; H01L 23/495

(52) U.S. Cl. 257/676; 438/123; 257/737; 257/783

(57) ABSTRACT

The invention discloses a chip-under-tape package structure including a flexible substrate, a chip, a plurality of connecting members, a plurality of stud bumps, and a potting adhesive. The flexible substrate includes a plurality of inner pads and a plurality of outer pads. The chip is attached to a lower surface of the flexible substrate and has an active surface thereon providing a plurality of bonding pads which each corresponds to one of the inner pads. Each of the connecting members functions electrically connecting one of the bonding pads with the inner pad corresponding to said one bonding pad. Each of the stud bumps is attached to one of the outer pads. The potting adhesive is coated to seal the connecting members. Accordingly, the invention is capable of preventing the outer pads from being contaminated by the potting adhesive and suitable for low-cost package of high frequency memory chip.

### BACKGROUND OF THE INVENTION

1. Field of the Invention

The invention relates to a chip-under-tape (CUT) package structure and manufacture thereof, and more particularly to a CUT package structure and manufacture thereof capable of effectively reducing package cost of high frequency memory chip.

2. Description of the Prior Art

As the development of integrated circuit tends towards high efficiency and miniaturization, the package of semiconductor chip also gradually tends towards high frequency and low-cost package, and there are various package types developed for different number of pins. However, when a chip is packaged, low-cost package is desired without reducing the computation frequency of the chip. In the conventional memory package, a synchronous dynamic random access memory (SDRAM) with frequency less then 150 MHz and a double data rate (DDR) DRAM with frequency less than 400 MHz both are packaged by thin small outline package (TSOP). At start, the TSOP attaches a conducting wire stand with a plurality of pins onto an active surface of a memory chip. Afterwards, a bonding wire is used for connecting the memory chip and the pins, and then a sealant is used for sealing the memory chip and the inner part of the pins. The outer part of the pins is exposed for electrical connection. However, the TSOP is not suitable for packaging high frequency memory chip.

Nowadays, the type of substrate on chip (SOC) is often used to package the DDR DRAM chip with frequency higher than 400 MHz. Referring to FIG. 1, FIG. 1 is a schematic diagram illustrating a semiconductor package structure 10 of the prior art. The semiconductor package structure 10 includes a substrate 12, a memory chip 14, a plurality of bonding wires, a molding adhesive 18, and a plurality of bonding balls 20. The substrate 12 has an upper surface 120, a lower surface 122, and a hole 124 formed through the upper surface 120 and the lower surface 122. The substrate 12 is a miniaturized high density printed circuit board (PCB) (e.g. BT substrate). The substrate 12 further includes multiple circuit layers and a plurality of ball pads 126 formed on the upper surface 120. The chip 14 has an active surface 140 and a back surface 142 and includes a plurality of bonding pads 144, wherein the bonding pads are formed on the active surface 140.

Referring to FIG. 2 together with FIG. 1, FIG. 2 is a flowchart showing the method of manufacturing the semiconductor package structure. The method of the prior art includes the following steps of: (a) attaching the active surface 140 of the chip 14 onto the lower surface 122 of the substrate 12 by a chip-attaching adhesive 22, such that the bonding pads 144 of the chip 14 are all exposed in the hole 124 of the substrate 12; (b) utilizing the bonding wires 16 via the hole 124 to connect the bonding pads of the chip 14 and the substrate 12; (c) coating the molding adhesive 18 to the lower surface 122 of the substrate 12 and the hole 124 to seal the chip 14 and the bonding wires 16, wherein before the molding adhesive 18 is coated, the upper surface 120 and the lower surface 122 of the substrate 12 both are clamped by appropriate mold; (d) attaching each of the bonding balls 20 onto one of the ball pads 126. Accordingly, because the transmission path is effectively shortened, the semiconductor package structure 10 can be applied to package high frequency memory chip. However, the aforementioned SOC package still has the following problems:

(1) The molding adhesive 18 will probably contaminate the ball pads 126 via the gap between the upper surface 120 of the substrate 12 and the mold, such that each of the bonding balls 20 cannot be attached to the corresponding ball pad 126 appropriately.

(2) Additional apparatus is necessary for attaching the bonding balls 20 to the ball pads 126, such that the package cost and time thereof will increase.

(3) The humidity-resist capability of the substrate 12 is bad.

### SUMMARY OF THE INVENTION

An objective of the invention is to provide a chip-under-tape (CUT) structure and manufacture thereof for reducing the package cost and time thereof of high frequency memory chip.

According to a preferred embodiment of the invention, the CUT package structure includes a flexible substrate, a chip, a plurality of connecting members, a plurality of stud bumps, and a potting adhesive. The flexible substrate has an upper surface and a lower surface and includes a plurality of inner pads and a plurality of outer pads. The chip is attached to the lower surface of the flexible substrate and has an active surface, wherein the active surface thereon provides a plurality of bonding pads which each corresponds to one of the inner pads. Each of the connecting members functions electrically connecting one of the bonding pads of the chip with the corresponding inner pad of the flexible substrate. Each of the stud bumps is attached to one of the outer pads of the flexible substrate. The potting adhesive is coated to seal the connecting members. In other words, the potting adhesive replaces the bonding balls and the molding adhesive to seal the connecting members.

Accordingly, the invention is capable of preventing the outer pads from being contaminated by the potting adhesive. Moreover, the invention can be applied to low-cost package of high frequency memory chip.

The advantage and spirit of the invention may be understood by the following recitations together with the appended drawings.

### BRIEF DESCRIPTION OF THE APPENDED DRAWINGS

FIG. 1 is a schematic diagram illustrating a semiconductor package structure of the prior art.

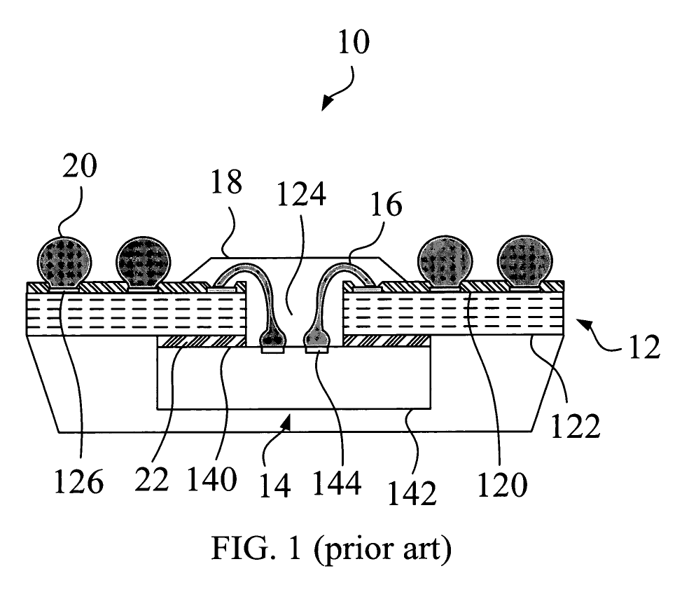

FIG. 2 is a flowchart showing the method of manufacturing the semiconductor package structure.

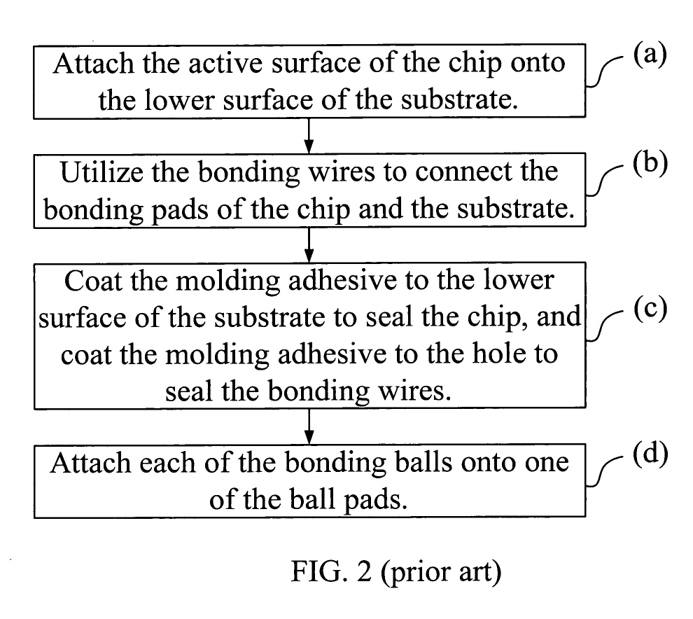

FIG. 3 is a schematic diagram illustrating a CUT package structure according to a first preferred embodiment of the invention.

FIG. 4 is a schematic diagram illustrating the flexible substrate shown in FIG. 3.

FIG. 5 is a flowchart showing the method of manufacturing the CUT package structure according to the first preferred embodiment of the invention.

FIG. 6 is a schematic diagram illustrating a CUT package structure according to a second preferred embodiment of the invention.

FIG. 7 is a flowchart showing the method of manufacturing the CUT package structure according to the second preferred embodiment of the invention.

### DETAILED DESCRIPTION OF THE INVENTION

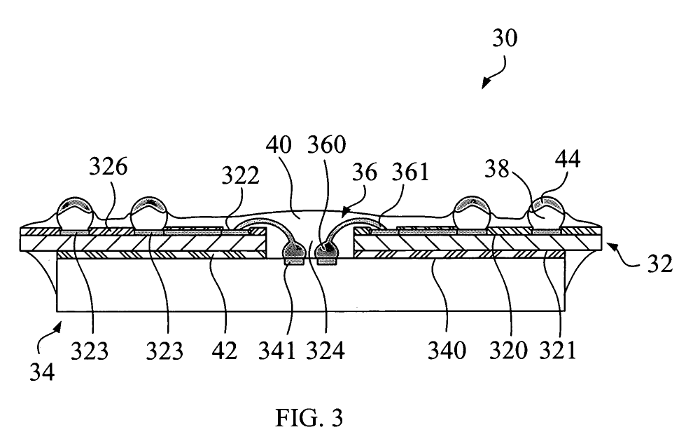

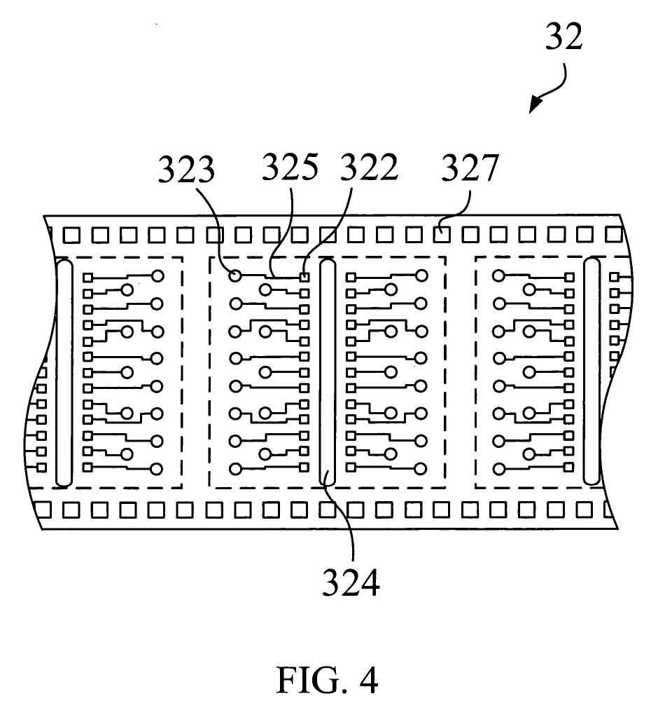

Referring to FIG. 3 and FIG. 4, FIG. 3 is a schematic diagram illustrating a CUT package structure 30 according to a first preferred embodiment of the invention. FIG. 4 is a schematic diagram illustrating the flexible substrate 32 shown in FIG. 3. The chip-under-tape (CUT) package structure 30 includes a flexible substrate 32, a chip 34, a plurality of connecting members 36, a plurality of stud bumps 38, and a potting adhesive 40. The flexible substrate 32 can be a low-cost soft PCB with single layer, as shown in FIG. 4. In a preferred embodiment, the thickness of the flexible substrate 32 is less than 0.2 mm. The potting adhesive 40 is one selected from the group consisting of an anisotropic conductive paste (ACP), an anisotropic conductive film (ACF), a non-conductive paste (NCP), and a non-conductive film (NCF).

As shown in FIG. 3, the flexible substrate 32 has an upper surface 320 and a lower surface 321 and includes a plurality of inner pads 322 and a plurality of outer pads 323. The flexible substrate 32 also has an opening 324, and the inner pads 322 and the outer pads 323 are formed on the upper surface 320 of the flexible substrate 32. As shown in FIG. 4, the flexible substrate 32 further includes a plurality of connecting lines 325 for connecting each of the inner pads 322 with the corresponding outer pad 323. The inner pads 322 are arranged around the hole 324, and the outer pads can be arranged in matrix. In the first embodiment, the hole 324 is long and narrow, and the flexible substrate 32 has an electrically insulated layer 326 for covering each of the connecting lines 325. Furthermore, each of the connecting line 325 is capable of transmitting high frequency signals. Before package, there is a plurality of equidistant sprocket holes 327 along both edges of the flexible substrate 32 for a rolling belt to transport the flexible substrate 32.

As shown in FIG. 3, the chip 34 is attached to the lower surface 321 of the flexible substrate 32. The chip 34 has an active surface 340, and the active surface 340 thereon provides a plurality of bonding pads 341, wherein each of the bonding pads 341 corresponds to one of the inner pads 322 and is exposed in the opening 324. In the first embodiment, the chip 34 can be a memory chip or other semiconductor chips with low terminals. In a preferred embodiment, the chip 34 can be a DRAM with frequency higher than 400 MHz.

In the first embodiment, each of the connecting members 36 is a bonding wire, respectively. As shown in FIGS. 3 and 4, each of the bonding wires 36 has a first end 360 and a second end 361. Each of the bonding wires 36 is via the first end 360 thereof connected to one of the bonding pads 341 and via the second end 361 thereof connected to the inner pad 322 corresponding to the one bonding pad 341, such that the chip 34 is electrically connected to the flexible substrate 32 by the bonding wires 36. Furthermore, each of the stud bumps 38 is attached to one of the outer pads 323 to be an outside connecting end. Afterwards, the potting adhesive 40 is coated to seal the bonding wires 36 and cover the stud bumps 38. Moreover, the CUT package structure 30 further includes a chip-attaching adhesive 42 coated between the active surface 340 of the chip 34 and the lower surface 321 of the flexible substrate 32. The chip-attaching adhesive 42 is one selected from the group consisting of a B-stage solidified film, an anisotropic conductive paste (ACP), an anisotropic conductive film (ACF), a non-conductive paste (NCP), and a non-conductive film (NCF). The chip-attaching adhesive 42 is better to be a B-stage solidified film and coated before coating of the potting adhesive 40. The CUT package structure 30 further includes a solder paste 44 coated on the stud bumps 38, so as to improve the surface mount technology (SMT).

In a preferred embodiment, the chip 34 can be attached to the lower surface 321 of the flexible substrate 32 by a eutectic process.

In another preferred embodiment, the chip 34 can also be attached to the lower surface 321 of the flexible substrate 32 by an ultrasonic process.

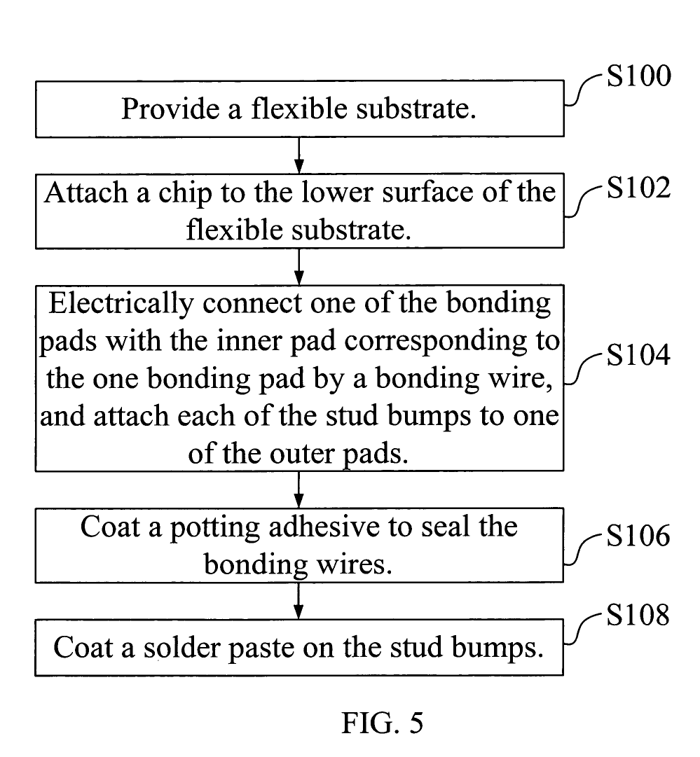

Referring to FIG. 5, FIG. 5 is a flowchart showing the method of manufacturing the CUT package structure according to the first preferred embodiment of the invention. According to the aforementioned first embodiment, the method includes the following steps. At start, step S100 is performed to provide a flexible substrate 32, wherein the flexible substrate 32 has an upper surface 320 and a lower surface 321 and includes a plurality of inner pads 322 and a plurality of outer pads 323. The flexible substrate 32 also has an opening 324, and the inner pads 322 and the outer pads 323 are formed on the upper surface 320 of the flexible substrate 32. Afterwards, step S102 is performed. In step S102, the flexible substrate 32 is transported to a chip-attaching device (not shown) by a rolling belt (not shown), and then a chip 34 is attached to the lower surface 321 of the flexible substrate 32. The chip 34 has an active surface 340, and the active surface 340 thereon provides a plurality of bonding pads 341, wherein each of the bonding pads 341 corresponds to one of the inner pads 322 and is exposed in the opening 324. Step S104 is then performed. In step S104, the flexible substrate 32 with the attached chip 34 is transported to a wire-bonding device (not shown) by the rolling belt, and then each of the bonding wires 36 is wire-bonded to electrically connect one of the bonding pads 341 of the chip 34 with the inner pad 322 of the flexible substrate 32 corresponding to the one bonding pad 341, and each of the stud bumps 38 is attached to one of the outer pads 323 of the flexible substrate 32. Step S106 is then performed. In step S106, the flexible substrate 32 is transported to an adhesive-coating device (not shown) by the rolling belt, and then a potting adhesive 40 is coated to seal the bonding wires 36. Step S108 is then performed. In step S108, a solder paste 44 is coated on the stud bumps 38 to improve the SMT.

Compared to the prior art, the first embodiment of the invention utilizes the potting adhesive 40 to seal the bonding wires 36 instead of the bonding balls and the molding adhesive of the prior art, so the invention is capable of preventing the outer pads 323 from being contaminated by the potting adhesive 40. Accordingly, the invention can be applied to low-cost package of high frequency memory chip. Moreover, the area of the upper surface 320 of the flexible substrate 32 can be designed to be smaller than or equal to 1.5 times the area of the active surface 340 of the chip 34, such that the CUT package structure 30 is formed as a chip scale package (CSP).

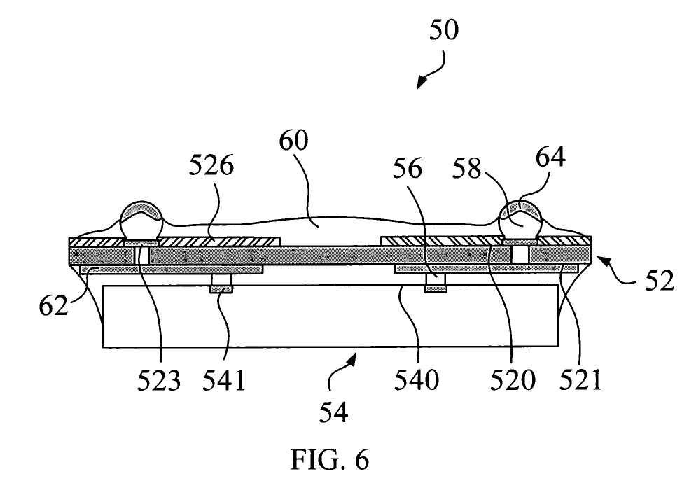

Referring to FIG. 6, FIG. 6 is a schematic diagram illustrating a CUT package structure 50 according to a second preferred embodiment of the invention. The CUT package structure 50 includes a flexible substrate 52, a chip 54, a plurality of connecting members 56, a plurality of stud bumps 58, and a potting adhesive 60. The flexible substrate 52 can be a low-cost soft PCB with single layer. In a preferred embodiment, the thickness of the flexible substrate 52 is less than 0.2 mm.

As shown in FIG. 6, the flexible substrate 52 has an upper surface 520 and a lower surface 521 and includes a plurality of inner pads (not shown) and a plurality of outer pads 523, wherein the outer pads 523 are formed on the upper surface 520 of the flexible substrate 52, the inner pads are formed on the lower surface 521 of the flexible substrate 52. The flexible substrate 52 further includes a lead layer 62 for connecting each of the inner pads with the corresponding outer pad 523. Furthermore, the lead layer 62 can transmit high frequency signals. Before package, there is a plurality of equidistant sprocket holes (not shown) along both edges of the flexible substrate 52 for a rolling belt to transport the flexible substrate 52. In the second embodiment, the flexible substrate 52 has an electrically insulated layer 526 for covering the upper surface 520.

As shown in FIG. 6, the chip 54 is attached to the lower surface 521 of the flexible substrate 52. The chip 54 has an active surface 540, and the active surface 540 thereon provides a plurality of bonding pads 541, wherein each of the bonding pads 541 corresponds to one of the inner pads. In the second embodiment, the chip 54 can be a memory chip or other semiconductor chips with low terminals. In a preferred embodiment, the chip 54 can be a DRAM with frequency higher than 400 MHz.

In a preferred embodiment, the chip 54 can be attached to the lower surface 521 of the flexible substrate 52 by a eutectic process.

In another preferred embodiment, the chip 54 can also be attached to the lower surface 521 of the flexible substrate 52 by an ultrasonic process.

In the second embodiment, each of the connecting members 56 is a bump (e.g. stud bump), respectively. As shown in FIG. 6, each of the bumps 56 is used for electrically connecting one of the bonding pads 541 of the chip 54 with the inner pad of the flexible substrate 52 corresponding to the one bonding pad 541, so as to shorten the transmission path. Furthermore, each of the stud bumps 58 is attached to one of the outer pads 523 to be an outside connecting end. Afterwards, the potting adhesive 60 is coated to seal the bumps 56 and cover the stud bumps 58. Moreover, the CUT package structure 50 further includes a solder paste 64 coated on the stud bumps 58, so as to improve the SMT.

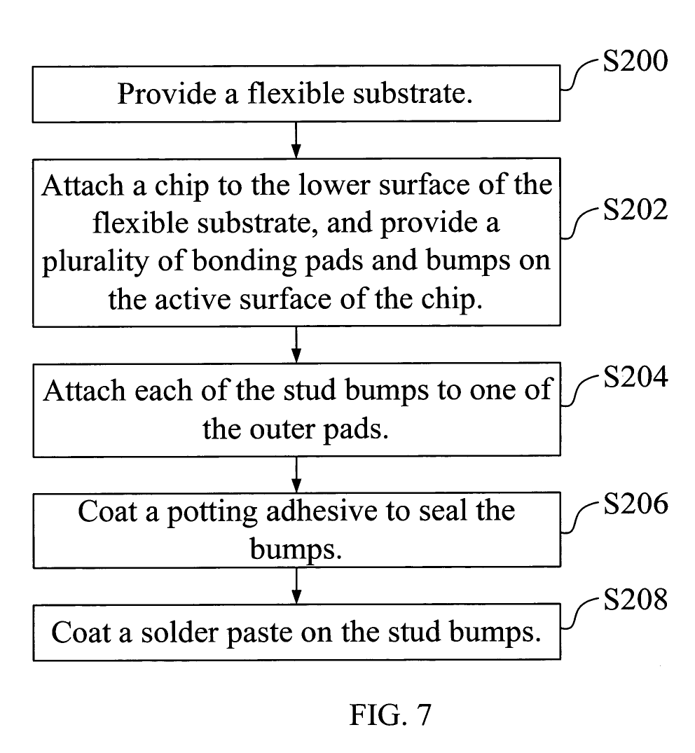

Referring to FIG. 7, FIG. 7 is a flowchart showing the method of manufacturing the CUT package structure according to the second preferred embodiment of the invention. According to the aforementioned second embodiment, the method includes the following steps. At start, step S200 is performed to provide a flexible substrate 52, wherein the flexible substrate 52 has an upper surface 520 and a lower surface 521 and includes a plurality of inner pads and a plurality of outer pads 523. The outer pads 523 are formed on the upper surface 520 of the flexible substrate 52, and the inner pads are formed on the lower surface 521 of the flexible substrate 52. The flexible substrate 52 further includes a lead layer 62 for connecting each of the inner pads with the corresponding outer pad 523. Afterwards, step S202 is performed. In step S202, the flexible substrate 52 is transported to a chip-attaching device (not shown) by a rolling belt (not shown), and then a chip 54 is attached to the lower surface 521 of the flexible substrate 52. The chip 54 has an active surface 540, and the active surface 540 thereon provides a plurality of bonding pads 541 and a plurality of bumps 56, wherein each of the bonding pads 541 corresponds to one of the inner pads, and each of the bumps 56 is used for electrically connecting one of the bonding pads 541 of the chip 54 with the inner pad of the flexible substrate 52 corresponding to the one bonding pad 541. Step S204 is then performed. In step S204, the flexible substrate 52 with the attached chip 54 is transported to a wire-bonding device (not shown) by the rolling belt, and then each of the stud bumps 58 is attached to one of the outer pads 523 of the flexible substrate 52. Step S206 is then performed. In step S206, the flexible substrate 52 is transported to an adhesive-coating device (not shown) by the rolling belt, and then a potting adhesive 60 is coated to seal the bumps 56. Step S208 is then performed. In step S208, a solder paste 64 is coated on the stud bumps 58 to improve the SMT.

Moreover, according to another preferred embodiment of the invention, each of the bumps 56 of the aforementioned step S202 can also be pre-formed on one of the inner pads of the flexible substrate 52.

Compared to the prior art, the second embodiment of the invention utilizes the potting adhesive 60 to seal the bumps 56 instead of the bonding balls and the molding adhesive of the prior art, so the invention is capable of preventing the outer pads 523 from being contaminated by the potting adhesive 60. Accordingly, the invention can be applied to low-cost package of high frequency memory chip. Moreover, the area of the upper surface 520 of the flexible substrate 52 can be designed to be smaller than or equal to 1.5 times the area of the active surface 540 of the chip 54, such that the CUT package structure 50 is formed as a chip scale package (CSP).

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A chip-under-tape package structure, comprising:
a flexible substrate having an upper surface and a lower surface and comprising a plurality of inner pads and a plurality of outer pads;
a chip, attached to the lower surface of the flexible substrate, having an active surface, the active surface thereon providing a plurality of bonding pads which each corresponds to one of the inner pads;
a plurality of connecting members, each of the connecting members functioning electrically connecting one of the bonding pads of the chip with the inner pad of the flexible substrate corresponding to said one bonding pad; and
a plurality of stud bumps, each of the stud bumps being attached to one of the outer pads of the flexible substrate.

2. The structure of claim 1, wherein the flexible substrate also has an opening, the inner pads and the outer pads are formed on the upper surface, and the bonding pads of the chip are exposed in the opening.

3. The structure of claim 2, wherein each of the connecting members is a bonding wire, respectively.

4. The structure of claim 3, wherein each of the bonding wires has a first end and a second end, and is via the first end thereof connected to one of the bonding pads and via the second end thereof connected to the inner pad corresponding to said one bonding pad.

5. The structure of claim 2, further comprising a chip-attaching adhesive coated between the active surface of the chip and the lower surface of the flexible substrate.

6. The structure of claim 5, wherein the chip-attaching adhesive is one selected from the group consisting of an anisotropic conductive paste (ACP), an anisotropic conductive film (ACF), a non-conductive paste (NCP), and a non-conductive film (NCF).

7. The structure of claim 1, wherein the outer pads are formed on the upper surface of the flexible substrate, the inner pads are formed on the lower surface of the flexible substrate.

8. The structure of claim 7, wherein each of the connecting members is a bump, respectively.

9. The structure of claim 8, wherein the bump is a stud bump.

10. The structure of claim 7, wherein the flexible substrate further comprises a lead layer formed on the lower surface thereof and electrically connected to the chip.

11. The structure of claim 1, wherein each of the outer pads corresponds to one of the inner pads, the flexible substrate further comprises a plurality of connecting lines which each functions electrically connecting one of the inner pads with the outer pad corresponding to said one inner pad.

12. The structure of claim 1, further comprising a solder paste coated on the stud bumps.

13. The structure of claim 1, further comprising a potting adhesive coated to seal the connecting members.

14. The structure of claim 13, further comprising a chip-attaching adhesive coated between the active surface of the chip and the lower surface of the flexible substrate.

15. The structure of claim 14, wherein the chip-attaching adhesive is coated before coating of the potting adhesive.

16. The structure of claim 14, wherein the chip-attaching adhesive is one selected from the group consisting of a B-stage solidified film, an anisotropic conductive paste (ACP), an anisotropic conductive film (ACF), a non-conductive paste (NCP), and a non-conductive film (NCF).

17. The structure of claim 13, wherein the potting adhesive is one selected from the group consisting of an anisotropic conductive paste (ACP), an anisotropic conductive film (ACF), a non-conductive paste (NCP), and a non-conductive film (NCF).

18. The structure of claim 13, wherein the chip is attached to the lower surface of the flexible substrate by a eutectic process.

19. The structure of claim 13, wherein the chip is attached to the lower surface of the flexible substrate by an ultrasonic process.

20. The structure of claim 13, wherein the potting adhesive is coated over the stud bumps.

21. A method of manufacturing a chip-under-tape package structure, comprising steps of:
providing a flexible substrate which has an upper surface and a lower surface and comprises a plurality of inner pads and a plurality of outer pads;
attaching a chip onto the lower surface of the flexible substrate, the chip having an active surface thereon providing a plurality of bonding pads which each corresponds to one of the inner pads;
electrically connecting each of the inner pads via one of a plurality of connecting members with the bonding pad corresponding to said one inner pad; and
attaching each of a plurality of stud bumps onto one of the outer pads of the flexible substrate.

22. The method of claim 21, wherein the flexible substrate also has an opening, the inner pads and the outer pads are formed on the upper surface, and the bonding pads of the chip are exposed in the opening.

23. The method of claim 22, wherein each of the connecting members is a bonding wire, respectively.

24. The method of claim 23, wherein each of the bonding wires has a first end and a second end, and is via the first end thereof connected to one of the bonding pads and via the second end thereof connected to the inner pad corresponding to said one bonding pad.

25. The method of claim 22, further comprising the step of coating a chip-attaching adhesive between the active surface of the chip and the lower surface of the flexible substrate.

26. The method of claim 25, wherein the chip-attaching adhesive is one selected from the group consisting of an anisotropic conductive paste (ACP), an anisotropic conductive film (ACF), a non-conductive paste (NCP), and a non-conductive film (NCF).

27. The method of claim 21, wherein the outer pads are formed on the upper surface of the flexible substrate, the inner pads are formed on the lower surface of the flexible substrate.

28. The method of claim 27, wherein each of the connecting members is a bump, respectively.

29. The method of claim 28, wherein the bump is a stud bump.

30. The method of claim 27, wherein the flexible substrate further comprises a lead layer formed on the lower surface thereof and electrically connected to the chip.

31. The method of claim 21, wherein each of the outer pads corresponds to one of the inner pads, the flexible substrate further comprises a plurality of connecting lines which each functions electrically connecting one of the inner pads with the outer pad corresponding to said one inner pad.

32. The method of claim 21, further comprising the step of coating a solder paste onto the stud bumps.

33. The method of claim 21, further comprising the step of coating a potting adhesive to seal the connecting members.

34. The method of claim 33, further comprising the step of coating a chip-attaching adhesive between the active surface of the chip and the lower surface of the flexible substrate.

35. The method of claim 34, wherein the chip-attaching adhesive is coated before coating of the potting adhesive.

36. The method of claim 34, wherein the chip-attaching adhesive is one selected from the group consisting of a B-stage solidified film, an anisotropic conductive paste (ACP), an anisotropic conductive film (ACF), a non-conductive paste (NCP), and a non-conductive film (NCF).

37. The method of claim 33, wherein the potting adhesive is one selected from the group consisting of an anisotropic conductive paste (ACP), an anisotropic conductive film (ACF), a non-conductive paste (NCP), and a non-conductive film (NCF).

38. The method of claim 33, wherein the chip is attached to the lower surface of the flexible substrate by a eutectic process.

39. The method of claim 33, wherein the chip is attached to the lower surface of the flexible substrate by an ultrasonic process.

40. The method of claim 33, wherein the potting adhesive is coated over the stud bumps.
